(19) United States
(12) Patent Application Publication
(10) Pub. No.: US 2025/0311588 A1
(43) Pub. Date: Oct. 2, 2025

(54) DISPLAY DEVICE

(71) Applicant: Japan Display Inc., Tokyo (JP)

(72) Inventor: Tatsuya IDE, Tokyo (JP)

(73) Assignee: Japan Display Inc., Tokyo (JP)

(21) Appl. No.: 19/093,319

(22) Filed: Mar. 28, 2025

(30) Foreign Application Priority Data
Mar. 29, 2024 (JP) 2024-056358

(51) Int. Cl. H10K 59/80; H10K 59/122; H10K 77/10

(52) U.S. Cl. CPC H10K 59/80; H10K 59/122; H10K 77/111

(57) ABSTRACT

According to one embodiment, a display device includes a support substrate including a first resinous substrate, a second resinous substrate, and a first barrier layer provided between the first resinous substrate and the second resinous substrate and formed of an inorganic insulating material, and a plurality of display elements provided in a display area. The second resinous substrate adheres to the first barrier layer with a first adhesion strength under the display area. The support substrate has, between an end portion of the support substrate and the display area, an overlap area in which the second resinous substrate and the first barrier layer overlap each other with a second adhesion strength which is less than the first adhesion strength.

### CROSS-REFERENCE TO RELATED APPLICATION

This application is based upon and claims the benefit of priority from Japanese Patent Application No. 2024-056358, filed Mar. 29, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer.

Moreover, in recent years, flexible displays have been considered from various perspectives. In these flexible displays, a technique for preventing the break of wiring lines in a folded area has been required.

### BRIEF DESCRIPTION OF THE DRAWINGS

FIG. 1 is a plan view showing a configuration example of a display device DSP.

FIG. 2 is a diagram showing an example of the layout of subpixels SP1, SP2 and SP3.

FIG. 3 is the schematic cross-sectional view of a display panel 100 along the A-B line of FIG. 2.

FIG. 4 is the schematic cross-sectional view of the display panel 100 along the I-I′ line of FIG. 1.

FIG. 5 is a cross-sectional view in which a circuit layer 24 overlapping an overlap area OA is enlarged.

FIG. 6 is a plan view in which the third area A3 of a support substrate SUB is enlarged.

FIG. 7 is a diagram showing a state in which the display panel 100 shown in FIG. 1 is folded.

FIG. 8 is a diagram for explaining the neutral plane of the third area A3 in the embodiment.

FIG. 9 is a diagram for explaining the neutral plane of the third area A3 in a comparative example.

FIG. 10 is a diagram for explaining a manufacturing method for forming the overlap area OA.

FIG. 11 is a diagram for explaining another manufacturing method for forming the overlap area OA.

FIG. 12 is a plan view showing another configuration example of the display device DSP.

FIG. 13 is the schematic cross-sectional view of the display panel 100 along the II-II′ line of FIG. 12.

### DETAILED DESCRIPTION

Embodiments described herein aim to provide a display device which can prevent the reduction in reliability.

In general, according to one embodiment, a display device comprises a support substrate comprising a first resinous substrate having flexibility, a second resinous substrate having flexibility, and a first barrier layer provided between the first resinous substrate and the second resinous substrate and formed of an inorganic insulating material, and a plurality of display elements provided in a display area which displays an image above the support substrate. The second resinous substrate adheres tightly to the first barrier layer with a first adhesion strength under the display area. The support substrate has, between an end portion of the support substrate and the display area, an overlap area in which the second resinous substrate and the first barrier layer overlap each other with a second adhesion strength which is less than the first adhesion strength.

According to another embodiment, a display device comprises a display panel which has a first area including a display area displaying an image, a second area spaced apart from the first area, and a third area located between the first area and the second area, and is folded in the third area. The display panel comprises a support substrate comprising a first resinous substrate having flexibility, a second resinous substrate having flexibility, and a first barrier layer provided between the first resinous substrate and the second resinous substrate and formed of an inorganic insulating material, and a plurality of display elements provided in the display area above the support substrate. In the first area and the second area, the second resinous substrate adheres to the first barrier layer with a first adhesion strength. In the third area, the second resinous substrate overlaps the first barrier layer with a second adhesion strength which is less than the first adhesion strength.

The embodiments can provide a display device which can prevent the reduction in reliability.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”, and the negative direction of the Z-axis is referred to as “below” or “under”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

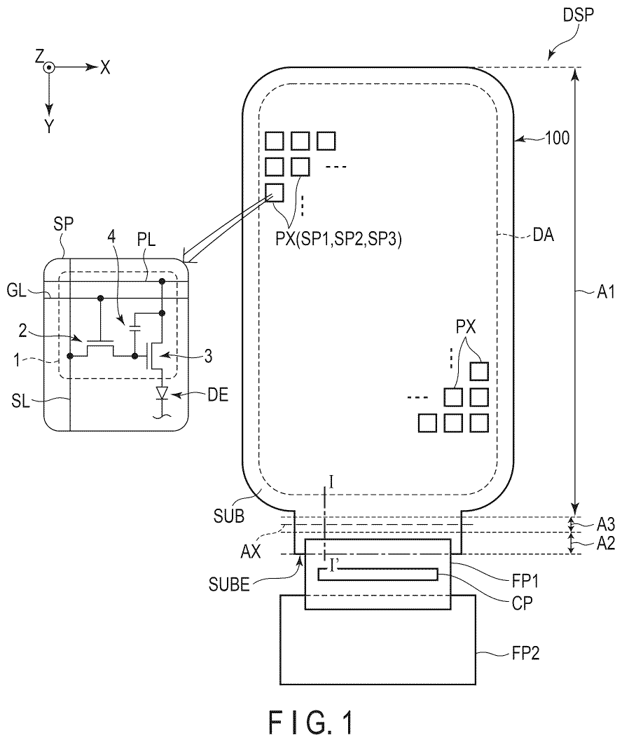

FIG. 1 is a plan view showing a configuration example of a display device DSP.

The display device DSP comprises a display panel 100, a flexible printed circuit FP1 and a flexible printed circuit FP2. The display panel 100 comprises a display area DA which displays images on an insulating support substrate SUB. The display area DA comprises a plurality of display elements DE as described later.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

The display element DE is, for example, an organic light emitting diode (OLED) as a light emitting element, and may be called an organic EL element.

As seen in plan view, the display panel 100 has a first area A1 including the display area DA, a second area A2 spaced apart from the first area A1, and a third area A3 located between the first area A1 and the second area A2. In the example shown in the figure, the first area A1, the third area A3 and the second area A2 are arranged in this order in the second direction Y. The third area A3 is a belt-like area which extends in the first direction X.

In this display panel 100, the first area A1 and the second area A2 are comparatively hard areas. The third area A3 is a flexible area compared to the first area A1, and is an area which can be folded based on the axis AX parallel to the first direction X.

The second area A2 is an area located between the third area A3 and the end portion SUBE of the support substrate SUB, and is a belt-like area which extends in the first direction X. Although not described in detail, the second area A2 comprises a terminal portion having a plurality of terminals, and is connected to the flexible printed circuit FP1 in the terminal portion. The flexible printed circuit FP1 is connected to another flexible printed circuit FP2. In the example shown in the figure, an integrated circuit chip CP for driving each of the pixels PX is mounted on the flexible printed circuit FP1.

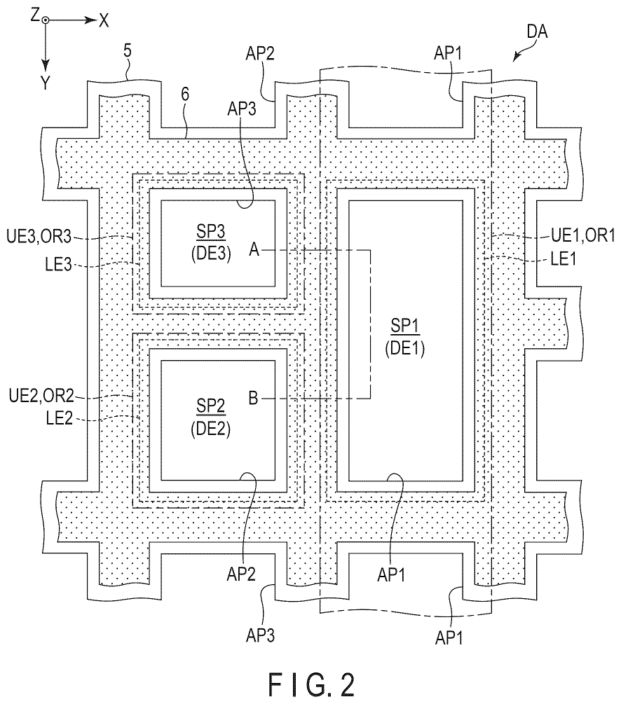

FIG. 2 is a diagram showing an example of the layout of subpixels SP1, SP2 and SP3.

In the example shown in the figure, subpixels SP2 and SP3 are arranged in the second direction Y. Subpixels SP2 and SP1 are arranged in the first direction X, and subpixels SP3 and SP1 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An insulating layer 5 and a partition 6 are provided in the display area DA. The insulating layer 5 has apertures AP1, AP2 and AP3 in subpixels SP1, SP2 and SP3, respectively. The insulating layer 5 having these apertures AP1, AP2 and AP3 may be called a rib.

The partition 6 overlaps the insulating layer 5 as seen in plan view. The partition 6 is formed into a grating shape surrounding the apertures AP1, AP2 and AP3. The partition 6 is conductive, and for example, is electrically connected to terminals having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The lower electrode LE1, the organic layer OR1 and the upper electrode UE1 are surrounded by the partition 6 as seen in plan view. The peripheral portion of each of the lower electrode LE1, the organic layer OR1 and the upper electrode UE1 overlaps the insulating layer 5 as seen in plan view.

The display element DE2 of subpixel SP2 comprises a lower electrode LE2, an upper electrode UE2 and an organic layer OR2 overlapping the aperture AP2. The lower electrode LE2, the organic layer OR2 and the upper electrode UE2 are surrounded by the partition 6 as seen in plan view. The peripheral portion of each of the lower electrode LE2, the organic layer OR2 and the upper electrode UE2 overlaps the insulating layer 5 as seen in plan view.

The display element DE3 of subpixel SP3 comprises a lower electrode LE3, an upper electrode UE3 and an organic layer OR3 overlapping the aperture AP3. The lower electrode LE3, the organic layer OR3 and the upper electrode UE3 are surrounded by the partition 6 as seen in plan view. The peripheral portion of each of the lower electrode LE3, the organic layer OR3 and the upper electrode UE3 overlaps the insulating layer 5 as seen in plan view.

In the example shown in the figure, the outer shapes of the lower electrodes LE1, LE2 and LE3 are shown by broken lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3.

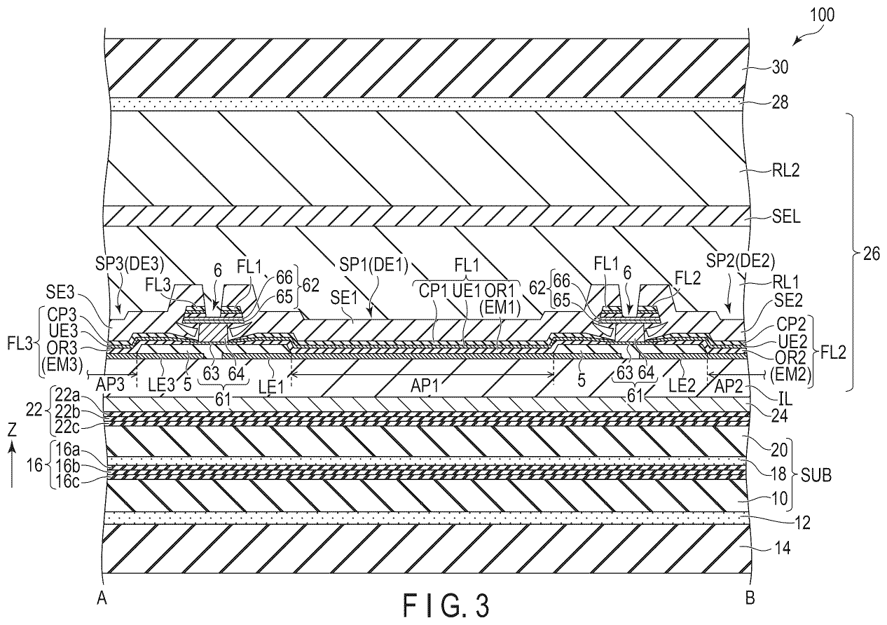

FIG. 3 is the schematic cross-sectional view of the display panel 100 along the A-B line of FIG. 2.

First, the support substrate SUB is explained. The support substrate SUB comprises resinous substrates 10 and 20 having flexibility, and a barrier layer 16.

The resinous substrates 10 and 20 are formed of, for example, polyimide. However, they may be formed of another resinous material as long as it has a sufficient flexibility. The resinous substrate 20 faces the resinous substrate 10 in a third direction Z and is located above the resinous substrate 10.

The barrier layer 16 is provided between the resinous substrate 10 and the resinous substrate 20 and is an inorganic insulating layer formed of an inorganic insulating material. The barrier layer 16 is, for example, a multilayer body in which thin films 16a, 16b and 16c are stacked in order. The thin films 16a and 16c are, for example, silicon oxide films. The thin film 16b is, for example, a silicon nitride film. It should be noted that the barrier layer 16 is not limited to the three-layer structure shown in the example of the figure and may be a multilayer body consisting of two or four or more layers or may be a single-layer body.

In the example shown in the figure, the support substrate SUB further comprises an adhesive layer 18 by which the barrier layer 16 and the resinous substrate 20 adhere to each other. The adhesive layer 18 is, for example, an amorphous silicon layer. It should be noted that the adhesive layer 18 may be formed of another material as long as the adhesive layer 18 improves the adhesiveness between the barrier layer 16 and the resinous substrate 20. Alternatively, instead of providing the adhesive layer 18, for example, an ashing process may be applied to the barrier layer 16 to roughen the surface of the barrier layer 16. By this process, the adhesiveness between the barrier layer 16 and the resinous substrate 20 may be improved.

For this support substrate SUB, a reinforcing board 14 is provided. The reinforcing board 14 is attached to the lower surface of the resinous substrate 10 (the surface opposite to the upper surface facing the resinous substrate 20) via a pressure-sensitive adhesive 12.

A barrier layer 22 is provided on the upper surface of the resinous substrate 20 (the surface opposite to the lower surface facing the resinous substrate 10) and is an inorganic insulating layer formed of an inorganic insulating material. The barrier layer 22 is, for example, a multilayer body in which thin films 22a, 22b and 22c are stacked in order. The thin films 22a and 22c are, for example, silicon oxide films. The thin film 22b is, for example, a silicon nitride film. It should be noted that the barrier layer 22 is not limited to the three-layer structure shown in the example of the figure and may be a multilayer body consisting of two or four or more layers or may be a single-layer body.

By combining two resinous substrates and two barrier layers 16 and 22, the barrier performance which prevents moisture from permeating the display area is enhanced.

A circuit layer 24 is provided on the barrier layer 22. The circuit layer 24 includes various circuits such as the pixel circuits 1 shown in FIG. 1, various wiring lines such as the scanning lines GL, the signal lines SL and the power lines PL and various insulating layers described later.

A display element layer 26 is provided on the circuit layer 24. The display element layer 26 comprises an insulating layer IL, the insulating layer 5, the display elements DE1, DE2 and DE3, the partition 6, sealing layers SE1, SE2 and SE3, a resin layer RL1, a sealing layer SEL, a resin layer RL2 and the like.

The insulating layer IL covers the circuit layer 24. The insulating layer IL is an organic insulating layer which planarizes the irregularities formed by the circuit layer 24.

The lower electrodes LE1, LE2 and LE3 are provided on the insulating layer IL and are spaced apart from each other. The insulating layer 5 is an inorganic insulating layer and is provided on the insulating layer IL and the lower electrodes LE1, LE2 and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the insulating layer 5. The lower electrodes LE1, LE2 and LE3 are connected to the pixel circuits 1 of subpixels SP1, SP2 and SP3, respectively, through contact holes provided in the insulating layer IL. It should be noted that the contact holes of the insulating layer IL are omitted in FIG. 3.

The partition 6 has a conductive lower portion 61 provided on the insulating layer 5, and an upper portion 62 provided on the lower portion 61.

In the example shown in the figure, the lower portion 61 has a bottom layer 63 provided on the insulating layer 5, and a stem layer 64 provided between the bottom layer 63 and the upper portion 62. The bottom layer 63 is thinner than the stem layer 64. The bottom layer 63 has a width greater than that of the stem layer 64. The both end portions of the bottom layer 63 protrude from the side surfaces of the stem layer 64.

The upper portion 62 has a thin film 65 provided on the stem layer 64, and a thin film 66 provided on the thin film 65. The upper portion 62 has a width greater than that of the stem layer 64. The both end portions of the upper portion 62 protrude from the side surfaces of the stem layer 64. In this specification, the side surfaces of the stem layer 64 are assumed to be, of the stem layer 64, the surfaces which extend between the bottom layer 63 and the upper portion 62.

In the example shown in the figure, the upper portion 62 has a width greater than that of the bottom layer 63. It should be noted that the bottom layer 63 may have a width greater than that of the upper portion 62.

The organic layer OR1 is in contact with the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and is in contact with the lower portion 61.

It should be noted that the contact between each of the upper electrodes UE1, UE2 and UE3 and the lower portion 61 includes a case where each of the upper electrodes UE1, UE2 and UE3 is directly in contact with the upper surface of the bottom layer 63 and a case where each of the upper electrodes UE1, UE2 and UE3 is directly in contact with the upper surface of the bottom layer 63 and is further directly in contact with a side surface of the stem layer 64. In this specification, the upper surface of the bottom layer 63 is assumed to include, of the bottom layer 63, the surface which is directly in contact with the stem layer 64, and the surface which protrudes from the stem layer 64 and faces the upper portion 62.

In the example shown in the figure, subpixel SP1 has a cap layer CP1 and the sealing layer SE1. Subpixel SP2 has a cap layer CP2 and the sealing layer SE2. Subpixel SP3 has a cap layer CP3 and the sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1. The sealing layer SE1 is in contact with the stem layer 64 and upper portion 62 of the partition 6 which surrounds the display element DE1.

The sealing layer SE2 is provided on the cap layer CP2, is in contact with the partition 6 and continuously covers each member of subpixel SP2. The sealing layer SE2 is in contact with the stem layer 64 and upper portion 62 of the partition 6 which surrounds the display element DE2.

The sealing layer SE3 is provided on the cap layer CP3, is in contact with the partition 6 and continuously covers each member of subpixel SP3. The sealing layer SE3 is in contact with the stem layer 64 and upper portion 62 of the partition 6 which surrounds the display element DE3.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

In the example shown in the figure, part of the stacked film FL1 is located on the partition 6 around subpixel SP1 and spaced apart from the stacked film FL1 located in the aperture AP1 (in other words, the portion which constitutes the display element DE1).

Similarly, part of the stacked film FL2 is located on the partition 6 around subpixel SP2 and spaced apart from the stacked film FL2 located in the aperture AP2 (in other words, the portion which constitutes the display element DE2).

Similarly, part of the stacked film FL3 is located on the partition 6 around subpixel SP3 and spaced apart from the stacked film FL3 located in the aperture AP3 (in other words, the portion which constitutes the display element DE3).

It should be noted that the stacked films FL1, FL2 and FL3 located on the partition 6 may be omitted in some cases. In this case, a cavity is formed between each of the sealing layers SE1, SE2 and SE3 and the partition 6.

Each of the end portions of the sealing layers SE1, SE2 and SE3 is located above the partition 6. In the example shown in the figure, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The resin layer RL1 covers the partition 6 and the sealing layers SE1, SE2 and SE3. When cavities are formed between the sealing layers SE1, SE2 and SE3 and the partition 6, these cavities are filled with the resin layer RL1.

The sealing layer SEL covers the resin layer RL1. The resin layer RL2 covers the sealing layer SEL.

An optical film 30 is, for example, a polarizer, and is attached to the resin layer RL2 via a sticking layer 28.

Each of the insulating layer 5, the sealing layers SE1, SE2 and SE3 and the sealing layer SEL is formed of, for example, an inorganic insulating material such as silicon nitride (SiNx), silicon oxide (Siox), silicon oxynitride (SiON) or aluminum oxide (Al₂O₃).

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. The stem layer 64 is formed of a material which is different from the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The thin film 65 is formed of, for example, a titanium-based material such as titanium or a titanium compound. The thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as indium tin oxide (ITO) and a reflective layer formed of a metal material such as silver. For example, each of the lower electrodes LE1, LE2 and LE3 is a multilayer body including a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

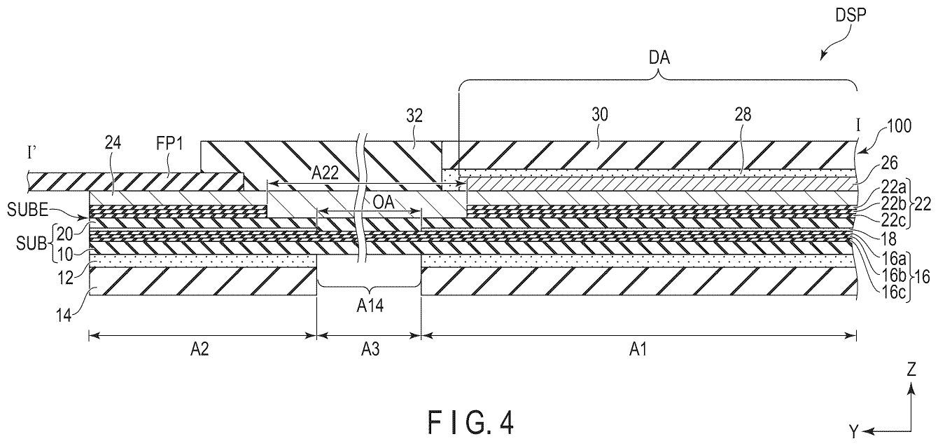

FIG. 4 is the schematic cross-sectional view of the display panel 100 along the I-I′ line of FIG. 1.

First, this specification focuses attention on the support substrate SUB. The resinous substrate 20 adheres tightly to the barrier layer 16 with a first adhesion strength in the area located under the display area DA or in the first area A1. The support substrate SUB has, between the end portion SUBE of the support substrate SUB and the display area DA, an overlap area OA in which the resinous substrate 20 and the barrier layer 16 overlap each other with a second adhesion strength which is less than the first adhesion strength.

In the example shown in the figure, the adhesive layer 18 is interposed between the barrier layer 16 and the resinous substrate 20. By the adhesive layer 18, the barrier layer 16 and the resinous substrate 20 adhere to each other in the area located under the display area DA or in the first area A1. To the contrary, the overlap area OA is an area in which the adhesive layer 18 is not present. In other words, the barrier layer 16 does not adhere to the resinous substrate 20 in the overlap area OA. This overlap area OA corresponds to the third area A3 of the display panel 100.

Further, in the example shown in the figure, the barrier layer 16 and the resinous substrate 20 adhere to each other by the adhesive layer 18 in the second area A2. In other words, the resinous substrate 20 adheres to the barrier layer 16 with the first adhesion strength in the first area A1 and the second area A2.

The reinforcing board 14 has an aperture A14 which overlaps the overlap area OA or the third area A3. In the example shown in the figure, the width of the aperture A14 in the second direction Y is coincident with the width of the overlap area OA or the third area A3 in the second direction Y. However, the widths may be different from each other.

The barrier layer 22 has an aperture A22 which overlaps the overlap area OA or the third area A3. In the example shown in the figure, the width of the aperture A22 in the second direction Y is different from that of the overlap area OA or the third area A3 in the second direction Y. However, the widths may be coincident with each other.

None of the display element layer 26 including the partition 6, the sticking layer 28 and the optical film 30 shown in FIG. 3 overlaps the overlap area OA or the third area A3.

A protective resin layer 32 is provided on the circuit layer 24, is in contact with the optical film 30 and overlaps part of the flexible printed circuit FP1. The protective resin layer 32 overlaps the overlap area OA or the third area A3. This protective resin layer 32 is formed of a material having plasticity.

It should be noted that plasticity is a property in which the material is deformed when a stress is applied, and the material does not return to the original shape even if the stress is removed. Plastic deformation is a deformation in which the material does not return to the original shape even if the stress is removed. Elasticity is a property in which the material is deformed when a stress is applied, and the material returns to the original shape when the stress is removed. Elastic deformation is a deformation in which the material returns to the original shape when the stress is removed.

Since the protective resin layer 32 is formed of a material having plasticity, it is plastically deformed when the display panel 100 is folded in the third area A3. For this reason, compared to a case where the protective resin layer 32 is formed of an elastic material, it is possible to reduce a reaction force in which the folded protective resin layer 32 attempts to return to the original shape. This configuration prevents the removal of the protective resin layer 32 from the optical film 30 and the removal of the protective resin layer 32 from the flexible printed circuit FP1, and further, the reaction force which acts on the third area A3 is reduced.

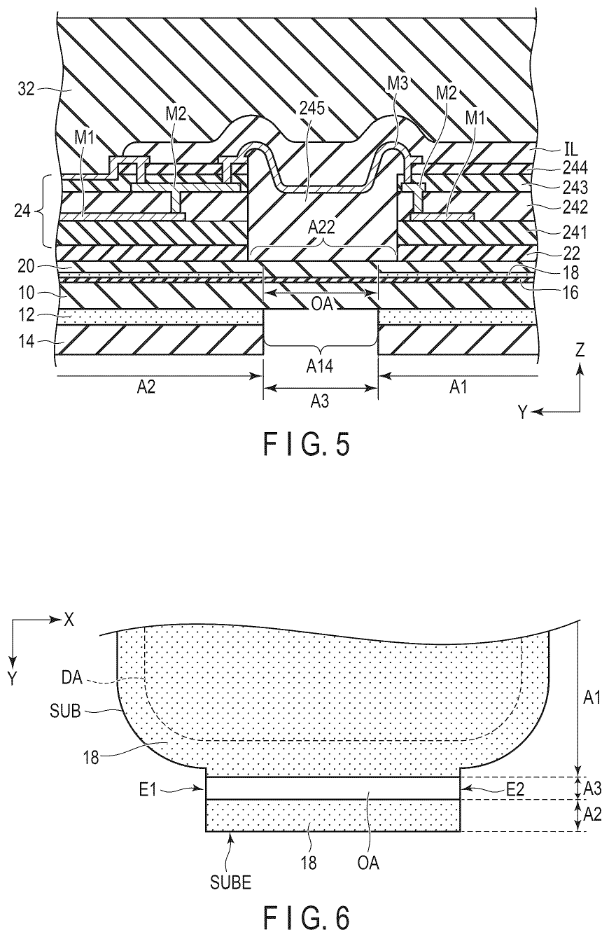

FIG. 5 is a cross-sectional view in which the circuit layer 24 overlapping the overlap area OA is enlarged.

The circuit layer 24 comprises insulating layers 241, 242, 243, 244 and 245 and metal layers M1, M2 and M3. The insulating layer 241 is provided on the barrier layer 22. The insulating layer 242 is provided on the insulating layer 241. The insulating layer 243 is provided on the insulating layer 242. The insulating layer 244 is provided on the insulating layer 243. These insulating layers 241, 242, 243 and 244 have an aperture overlapping the aperture A22 of the barrier layer 22. The insulating layer 245 is provided on the resinous substrate 20 in the aperture A22.

The insulating layers 241, 242, 243 and 244 are inorganic insulating layers. The insulating layer 245 is an organic insulating layer similar to the insulating layer IL. The insulating layer 245 and the insulating layer IL are formed of a material which elastically deforms. The material which elastically deforms is, for example, a resinous insulating material such as polyimide or acrylic.

The metal layer M1 is provided between the insulating layer 241 and the insulating layer 242. The metal layer M2 is provided between the insulating layer 242 and the insulating layer 243 and is electrically connected to the metal layer M1. The metal layer M3 is provided on the insulating layer 245 and further provided on the insulating layer 244, and is electrically connected to the metal layer M2.

The insulating layer IL covers the metal layer M3, the insulating layer 245 and the insulating layer 244. The protective resin layer 32 is provided on the insulating layer IL.

The metal layer M3 overlaps the overlap area OA or the third area A3. In other words, the metal layer M3 intersects with the third area A3 and electrically connects the metal layer M2 of the first area A1 and the metal layer M2 of the second area A2. The metal layer M3 is provided along the uneven upper surface of the insulating layer 245. Thus, the metal layer M3 is configured to extend when a tensile stress is applied to the metal layer M3.

The metal layer M3 is, for example, a multilayer body in which titanium (Ti), aluminum (Al) and titanium (Ti) are stacked in order. It should be noted that the material of the metal layer M3 is not limited to this example. For example, the metal layer M3 may be a single-layer body formed of tantalum (Ta), tungsten (W), molybdenum (Mo), copper (Cu) or silver (Ag), or a multilayer body consisting of these materials.

It should be noted that, in FIG. 5, the circuit layer 24 is enlarged in the third direction Z to explain the circuit layer 24. However, the thickness of each of the insulating layer 245 and the insulating layer IL is less than that of the resinous substrate 20.

FIG. 6 is a plan view in which the third area A3 of the support substrate SUB is enlarged.

The support substrate SUB has side edge portions E1 and E2 intersecting with the end portion SUBE. In the example shown in the figure, the end portion SUBE extends in the first direction X, and each of the side edge portions E1 and E2 extends in the second direction Y.

In the support substrate SUB, the area in which the adhesive layer 18 is provided is shown by the dotted pattern. The overlap area OA or the third area A3 in which the adhesive layer 18 is not provided extends in the first direction X and is formed into a belt-like shape which reaches the side edge portion E2 from the side edge portion E1. It should be noted that each of the aperture A14 of the reinforcing board 14 and the aperture A22 of the barrier layer 22 shown in FIG. 5 etc., is formed into a belt-like shape which reaches the side edge portion E2 from the side edge portion E1 in a manner similar to that of the overlap area OA.

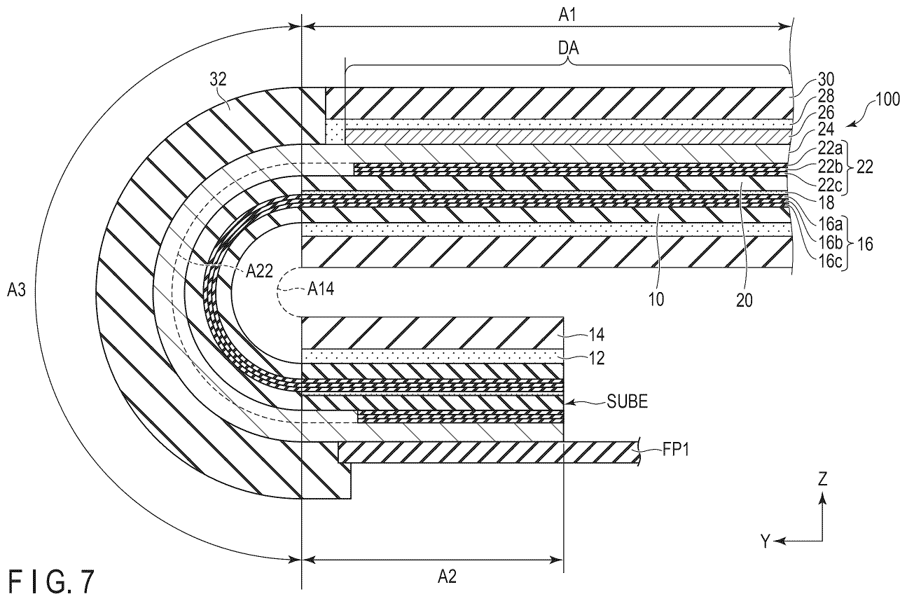

FIG. 7 is a diagram showing a state in which the display panel 100 shown in FIG. 1 is folded.

The display panel 100 is folded in the third area A3 where the adhesive layer 18 is not present. The second area A2 faces the first area A1 in the third direction Z. In the state where the display panel 100 is folded, the third area A3 overlaps each of the aperture A14 of the reinforcing board 14, the aperture A22 of the barrier layer 22 and the protective resin layer 32.

Since the display panel 100 is folded in the third area A3 in this manner, the width parallel to the second direction Y around the display area DA can be reduced, thereby realizing the reduction in the width of the frame.

As shown in FIG. 7, when the display panel 100 is folded in the third area A3, a tensile stress is generated on the projecting side of the neutral plane (neutral axis) of the third area A3 in accordance with the distance from the neutral plane. On the concave side of the neutral plane (neutral axis) of the third area A3, a compressive stress is generated in accordance with the distance from the neutral plane. In the third area A3, as explained with reference to FIG. 5, the metal layer M3 for electrically connecting the metal layer M2 of the first area A1 and the metal layer M2 of the second area A2 is provided. To prevent the break of the metal layer M3, the metal layer M3 should be preferably close to the neutral plane of the third area A3.

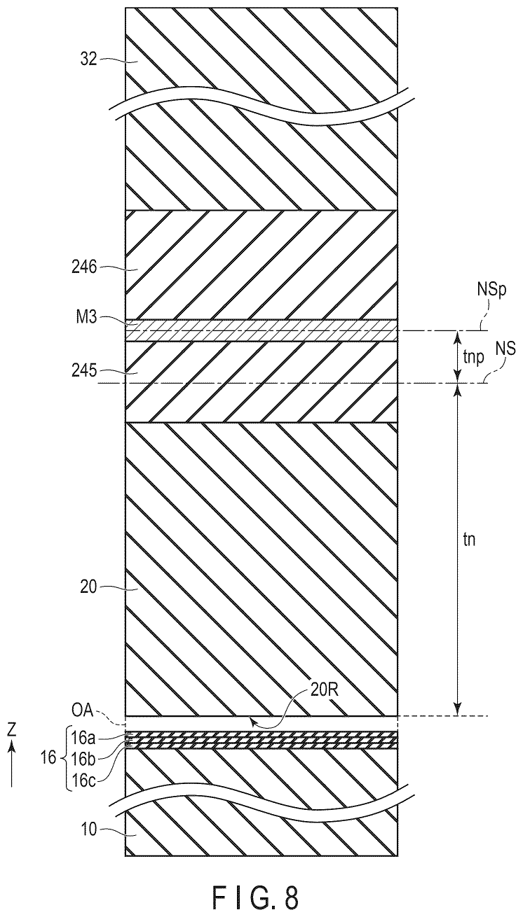

FIG. 8 is a diagram for explaining the neutral plane of the third area A3 in the embodiment.

As described above, the third area A3 corresponds to the overlap area OA, and the resinous substrate 20 is attached to the barrier layer 16 in the third area A3. Thus, the resinous substrate 10 or barrier layer 16 located under the resinous substrate 20 does not affect the position of the neutral plane of the upper multilayer body including the resinous substrate 20. In other words, the resinous substrate 20 does not receive a stress parallel to the interface of the resinous substrate 10 and barrier layer 16 located under the resinous substrate 20. As the protective resin layer 32 is formed of a material having plasticity, the protective resin layer 32 does not affect the position of the neutral plane of the upper multilayer body including the resinous substrate 20. Thus, the parameters of the resinous substrate 10, the barrier layer 16 or the protective resin layer 32, such as their respective thicknesses, are excluded from the calculation of the neutral plane.

When neutral plane NS of the third area A3 is obtained from calculation, neutral plane NS is present inside the insulating layer 245. In the third direction Z, the distance from the lower surface 20R of the resinous substrate 20 to neutral plane NS is defined as length tn. When the center of the metal layer M3 is defined as ideal neutral plane NSp, the distance from neutral plane NS to ideal neutral plane NSp is defined as length tnp.

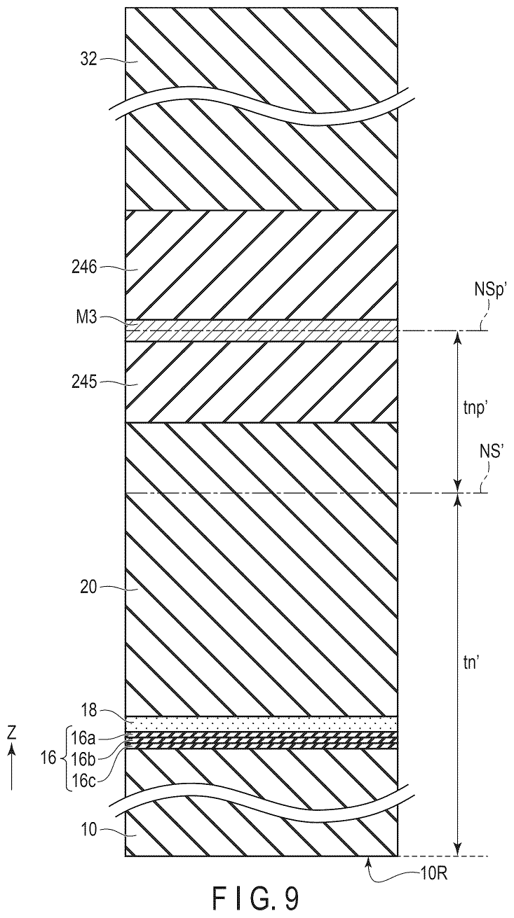

FIG. 9 is a diagram for explaining the neutral plane of the third area A3 in a comparative example.

In the comparative example, the resinous substrate 20 adheres to the barrier layer 16 by the adhesive layer 18 in the third area A3. In this case, the parameters of the resinous substrate 10 and the barrier layer 16, such as their respective thicknesses, need to be considered in the calculation of the neutral plane.

When neutral plane NS' of the third area A3 is obtained from calculation, neutral plane NS' is present inside the resinous substrate 20. In the third direction Z, the distance from the lower surface 10R of the resinous substrate 10 to neutral plane NS' is defined as length tn′. When the center of the metal layer M3 is defined as ideal neutral plane NSp′, the distance from neutral plane NS' to ideal neutral plane NSp′ is defined as length tnp′.

FIG. 8 and FIG. 9 show that length tnp is less than length tnp′ (tnp<tnp′). Thus, in this embodiment, relative to the comparative example, the metal layer M2 can be close to neutral plane NS.

As described above, a compressive stress acts on the structural elements located under neutral plane NS, and a tensile stress acts on the structural elements located above neutral plane NS.

In the examples shown in FIG. 8 and FIG. 9, the metal layer M3 is located above the neutral plane. Therefore, a tensile stress acts on the metal layer M3. In the embodiment, since the metal layer M3 (or the ideal neutral plane) comes close to the actual neutral plane, the tensile stress applied to the metal layer M3 can be reduced. This configuration prevents the break of the metal layer M3, thereby preventing the reduction in reliability.

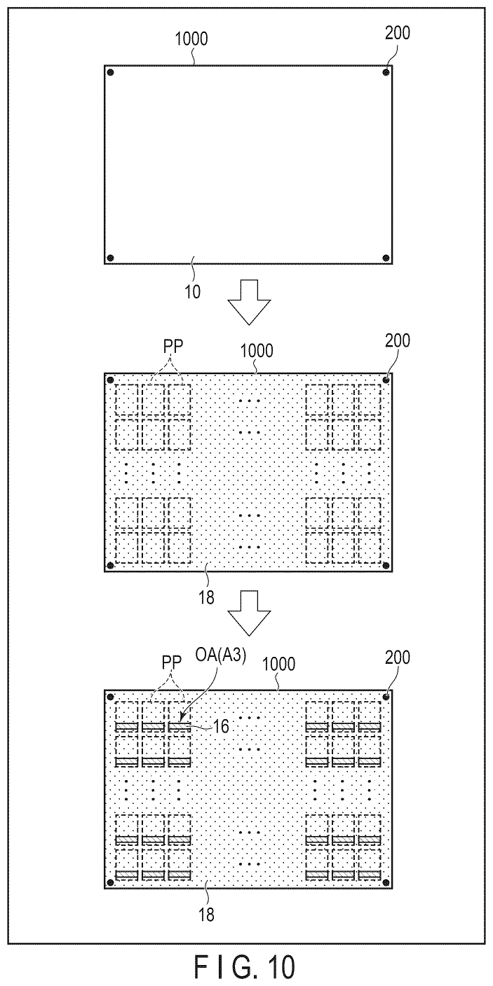

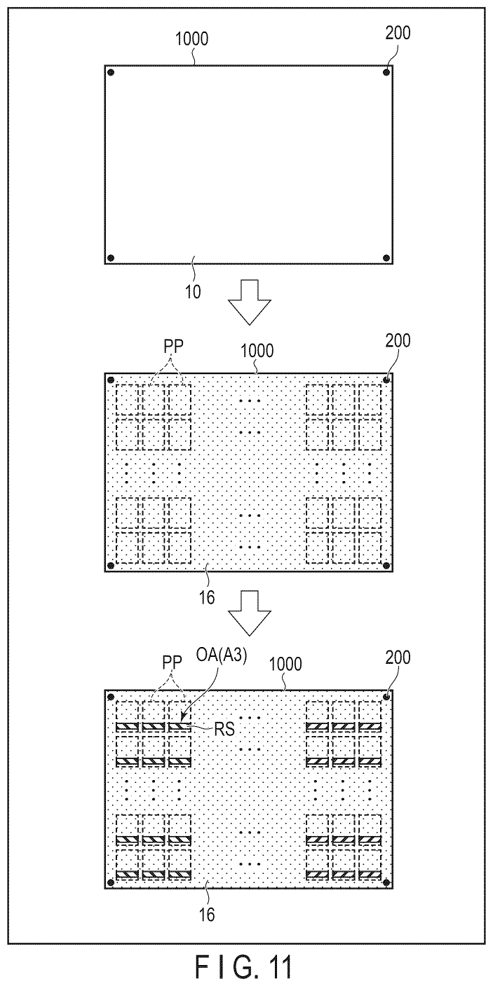

FIG. 10 is a diagram for explaining a manufacturing method for forming the overlap area OA.

First, as shown in the upper stage of FIG. 10, the resinous substrate 10 is formed on a large mother substrate 1000. Subsequently, a plurality of alignment marks 200 are formed on the resinous substrate 10. The alignment marks 200 are formed of, for example, molybdenum-tungsten (MoW). It should be noted that the material of the alignment marks 200 is not limited to this example. For example, the alignment marks 200 may be formed as a single-layer body of titanium (Ti), aluminum (Al), tantalum (Ta), tungsten (W), molybdenum (Mo), copper (Cu) or silver (Ag), or a multilayer body consisting of these materials.

Subsequently, as shown in the middle stage of FIG. 10, the barrier layer 16 and the adhesive layer 18 are formed in order on the whole surface of the resinous substrate 10. Each area surrounded by broken lines in the figure is a panel area PP extracted as the display panel 100 from the mother substrate 1000. The barrier layer 16 and the adhesive layer 18 are formed over a plurality of panel areas PP.

Subsequently, as shown in the lower stage of FIG. 10, a photolithography process is performed based on the alignment marks 200. In the adhesive layer 18, only the adhesive layer 18 of an area corresponding to the overlap area OA or the third area A3 is removed. In the area where the adhesive layer 18 has been removed, the barrier layer 16 is exposed.

Subsequently, although the illustration is omitted, the resinous substrate 20 is formed, and the barrier layer 22 having the aperture A22 is formed, and the circuit layer 24 is formed. The process of forming the aperture A22 and the process of forming the circuit layer 24 are performed based on the alignment marks 200. By this process, the overlap area OA, the aperture A22 and the circuit layer 24 (particularly, the metal layer M3) can be formed at desired positions.

FIG. 11 is a diagram for explaining another manufacturing method for forming the overlap area OA.

First, as shown in the upper stage of FIG. 11, the resinous substrate 10 is formed on the large mother substrate 1000. Subsequently, a plurality of alignment marks 200 are formed on the resinous substrate 10.

Subsequently, as shown in the middle stage of FIG. 11, the barrier layer 16 is formed on the whole surface of the resinous substrate 10. The barrier layer 16 is formed over a plurality of panel areas PP.

Subsequently, as shown in the lower stage of FIG. 11, each resist RS is patterned based on the alignment marks 200. In the barrier layer 16, only an area corresponding to the overlap area OA or the third area A3 is covered with the resist RS. Subsequently, an ashing process is applied to the barrier layer 16. By this process, the surface of the barrier layer 16 exposed from the resist RS is made rougher than that of the barrier layer 16 covered with the resist RS. Subsequently, the resist RS is removed.

Subsequently, although the illustration is omitted, the resinous substrate 20 is formed, and the barrier layer 22 having the aperture A22 is formed, and the circuit layer 24 is formed. The process of forming the aperture A22 and the process of forming the circuit layer 24 are performed based on the alignment marks 200. By this process, the overlap area OA, the aperture A22 and the circuit layer 24 (particularly, the metal layer M3) can be formed at desired positions.

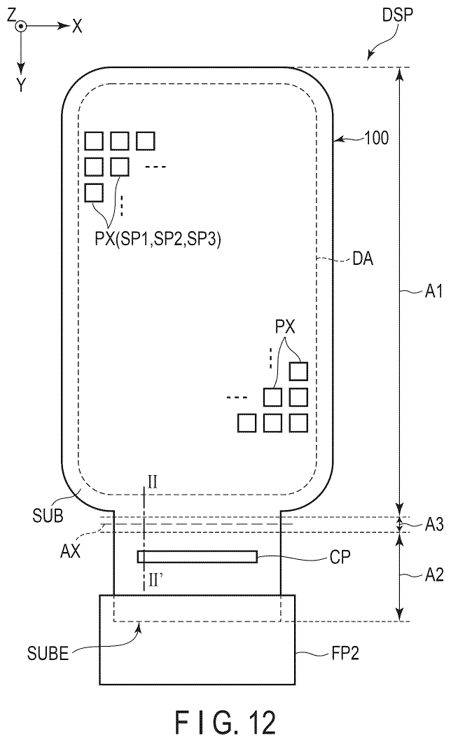

FIG. 12 is a plan view showing another configuration example of the display device DSP.

The configuration example shown in FIG. 12 is different from that shown in FIG. 1 in respect that the integrated circuit chip CP is mounted in the second area A2, and further, the flexible printed circuit FP2 is connected in the second area A2. In the configuration example shown in FIG. 12, the flexible printed circuit FP1 shown in FIG. 1 is omitted.

As seen in plan view, the display panel 100 has the first area A1 including the display area DA, the second area A2 spaced apart from the first area A1, and the third area A3 located between the first area A1 and the second area A2. The third area A3 is a belt-like area extending in the first direction X, and is an area which can be folded based on the axis AX parallel to the first direction X.

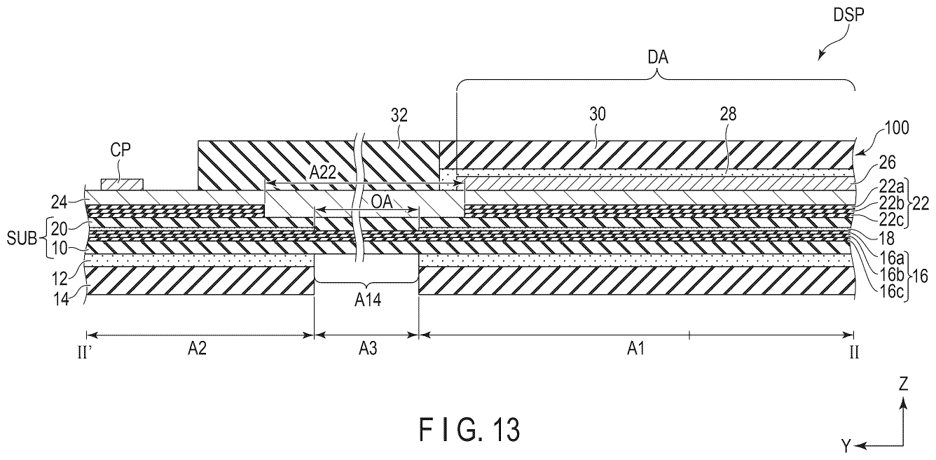

FIG. 13 is the schematic cross-sectional view of the display panel 100 along the II-II′ line of FIG. 12.

The overlap area OA in which the barrier layer 16 and the resinous substrate 20 overlap each other corresponds to the third area A3, and overlaps each of the aperture A14 of the reinforcing board 14, the aperture A22 of the barrier layer 22 and the protective resin layer 32.

None of the display element layer 26 including the partition 6, the sticking layer 28 and the optical film 30 shown in FIG. 3 overlaps the overlap area OA or the third area A3.

The integrated circuit chip CP is mounted on the circuit layer 24 in the second area A2.

The protective resin layer 32 is provided on the circuit layer 24, is in contact with the optical film 30 and does not overlap the integrated circuit chip CP. This protective resin layer 32 is formed of a material having plasticity.

In this configuration example, effects similar to those of the configuration example described earlier are obtained.

In the embodiment described above, for example, the resinous substrate 10 corresponds to a first resinous substrate. The resinous substrate 20 corresponds to a second resinous substrate.

The barrier layer 16 corresponds to a first barrier layer. The barrier layer 22 corresponds to a second barrier layer.

The side edge portion E1 corresponds to a first side edge portion. The side edge portion E2 corresponds to a second side edge portion.

The insulating layer 245 corresponds to a first organic insulating layer. The insulating layer IL corresponds to a second organic insulating layer.

Each of the sealing layers SE1, SE2 and SE3 corresponds to a first sealing layer. The sealing layer SEL corresponds to a second sealing layer.

The resin layer RL1 corresponds to a first resin layer. The resin layer RL2 corresponds to a second resin layer.

As explained above, the present embodiment can provide a display device which can prevent the reduction in reliability.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a support substrate comprising:
a first resinous substrate having flexibility;
a second resinous substrate having flexibility; and
a first barrier layer provided between the first resinous substrate and the second resinous substrate and formed of an inorganic insulating material; and
a plurality of display elements provided in a display area which displays an image above the support substrate, wherein
the second resinous substrate adheres to the first barrier layer with a first adhesion strength under the display area, and
the support substrate comprises, between an end portion of the support substrate and the display area, an overlap area in which the second resinous substrate and the first barrier layer overlap each other with a second adhesion strength which is less than the first adhesion strength.

2. The display device of claim 1, wherein
the support substrate has first and second side edge portions intersecting with the end portion, and
the overlap area is formed into a belt-like shape which reaches the second side edge portion from the first side edge portion.

3. The display device of claim 1, wherein
the support substrate further comprises an adhesive layer by which the first barrier layer and the second resinous substrate adhere to each other, and
the overlap area is an area in which the adhesive layer is not present.

4. The display device of claim 3, wherein
the adhesive layer is an amorphous silicon layer.

5. The display device of claim 1, further comprising a reinforcing board attached to the first resinous substrate, wherein
the reinforcing board has an aperture which overlaps the overlap area.

6. The display device of claim 1, further comprising a second barrier layer provided on the second resinous substrate and formed of an inorganic insulating material, wherein
the second barrier layer has an aperture which overlaps the overlap area.

7. The display device of claim 1, further comprising:
a first organic insulating layer provided on the second resinous substrate;
a metal layer provided on the first organic insulating layer; and
a second organic insulating layer which covers the metal layer, wherein
the metal layer overlaps the overlap area.

8. The display device of claim 7, wherein
the second organic insulating layer extends to the display area, and
each of the display elements comprises:
a lower electrode provided on the second organic insulating layer;
an organic layer provided on the lower electrode and including a light emitting layer; and
an upper electrode provided on the organic layer.

9. The display device of claim 8, further comprising:
an inorganic insulating layer which is provided on the second organic insulating layer in the display area and covers a peripheral portion of the lower electrode; and
a partition which surrounds each of the display elements, wherein
the partition has:
a lower portion which is provided on the inorganic insulating layer, is formed of a conductive material and is in contact with the upper electrode; and
an upper portion which is provided on the lower portion and protrudes from a side surface of the lower portion.

10. The display device of claim 9, wherein
the partition does not overlap the overlap area.

11. The display device of claim 9, further comprising:
a cap layer provided on the upper electrode;
a first sealing layer which is provided on the cap layer and individually covers each of the display elements;
a first resin layer provided on the first sealing layer;
a second sealing layer provided on the first resin layer;
a second resin layer provided on the second sealing layer; and
an optical film attached to the second resin layer.

12. The display device of claim 11, further comprising a protective resin layer which is provided on the second organic insulating layer and is in contact with the optical film, wherein
the protective resin layer overlaps the overlap area.

13. The display device of claim 12, wherein
the protective resin layer is formed of a material having plasticity.

14. A display device comprising:
a display panel which has a first area including a display area displaying an image, a second area spaced apart from the first area, and a third area located between the first area and the second area, and is folded in the third area, wherein
the display panel comprises:
a support substrate comprising a first resinous substrate having flexibility, a second resinous substrate having flexibility, and a first barrier layer provided between the first resinous substrate and the second resinous substrate and formed of an inorganic insulating material; and
a plurality of display elements provided in the display area above the support substrate,
in the first area and the second area, the second resinous substrate adheres to the first barrier layer with a first adhesion strength, and
in the third area, the second resinous substrate overlaps the first barrier layer with a second adhesion strength which is less than the first adhesion strength.

15. The display device of claim 14, wherein
the support substrate further comprises an adhesive layer by which the first barrier layer and the second resinous substrate adhere to each other in the first area and the second area, and
the third area is an area in which the adhesive layer is not present.

16. The display device of claim 14, wherein
the display panel further comprises a reinforcing board attached to the first resinous substrate, and
the reinforcing board has an aperture which overlaps the third area.

17. The display device of claim 14, wherein
the display panel further comprises a second barrier layer provided on the second resinous substrate and formed of an inorganic insulating material, and
the second barrier layer has an aperture which overlaps the third area.

18. The display device of claim 14, wherein
the display panel further comprises:
a first organic insulating layer provided on the second resinous substrate;
a metal layer provided on the first organic insulating layer; and
a second organic insulating layer which covers the metal layer, and
the metal layer overlaps the third area.

19. The display device of claim 18, wherein
the display panel further comprises a protective resin layer provided on the second organic insulating layer, and
the protective resin layer overlaps the third area.

20. The display device of claim 14, wherein
the display panel further comprises a partition which surrounds each of the display elements, and
the partition has a lower portion and an upper portion provided on the lower portion and protruding from a side surface of the lower portion, and does not overlap the third area.
